(19) United States
(12) Patent Application Publication
(10) Pub. No.: US 2003/0222310 A1
(43) Pub. Date: Dec. 4, 2003

(54) [METHOD OF FABRICATING THIN FILM TRANSISTOR ARRAY SUBSTRATE OF REFLECTIVE LIQUID CRYSTAL DISPLAY]

(76) Inventors: IVAN YANG-EN WU, TAIPEI (TW); FU-JEN KO, HSINCHU CITY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,926

(22) Filed: May 20, 2003

(30) Foreign Application Priority Data
May 30, 2002 (TW) 91111522

(51) Int. Cl. H01L 21/00; H01L 27/01; H01L 31/0392

(52) U.S. Cl. 257/347; 438/151; 438/159; 257/350

(57) ABSTRACT

A method of fabricating a thin film transistor array substrate of a reflective liquid crystal display includes providing a substrate, forming a gate electrode on the substrate, and then forming a gate-insulating layer covering over the substrate. The method further includes forming a channel layer above the gate, forming a source/drain electrode layer and a reflective electrode over the substrate using one photolithography process. A protection layer is formed over the substrate.

### CROSS REFERENCE TO RELATED APPLICATIONS

This application claims the priority benefit of Taiwan application serial no. 91111522, filed on May 30, 2002.

### BACKGROUND OF INVENTION

1. Field of Invention

This invention relates to a method of fabricating a thin film transistor array substrate of a reflective liquid crystal display. More particularly, this invention relates to a fabrication method for forming a thin film transistor array substrate in which the source/drain electrode and data line can be fabricated at the same time.

2. Description of Related Art

The fast growing on the multi-media industry is greatly benefiting from the great functional improvements on semiconductor devices or displaying devices. Among the displaying devices, the cathode ray tube (CRT) had been occupying the market because of its advantages of fine displaying quality and low cost. However, CRT has the problems in space occupation and power consumption. Since the demand has been increasing for displays with fine displaying quality, light weight, thin, short, and small size, and low power consumption, the thin film transistor liquid crystal display (TFT-LCD) has gradually become the dominant product in the market due to its fine displaying quality, light weight, thin, short and more compact size, as well as its low power consumption. However, the price of the liquid crystal displayers is usually high. Therefore, if its fabrication cost can be reduced, the liquid crystal displayers can be much more competitive over other products in the market.

Referring to FIG. 1 to FIG. 5, a group of fabrication process flow diagrams are shown for forming a conventional thin film transistor array substrate of a reflective liquid crystal displayer. In FIG. 1, a substrate 100 is provided. A gate electrode 102 and a scan line (not shown) connected with the gate electrode 102 are formed over the substrate 100.

Followed with FIG. 2, a gate-insulating layer 104 is formed in blanket over the substrate 100 and the gate electrode 102. A channel layer 106, which includes amorphous silicon material, is then formed over the gate insulating-layer 104.

Next, referring to FIG. 3 and FIG. 4, after the formation of the channel layer 106, a source/drain electrode region 108 and a data line (not shown) connected with one of the source/drain electrode 108 are formed at each side of the channel layer 106. Following that, a protection layer 1 10 is then formed over the substrate 100, covering the thin film transistor, which includes the gate electrode 102, the insulating layer 104, the channel layer 106, and the source/drain electrode region 108, as well as covering other regions of the substrate 100.

Finally, referring, to FIG. 5, a bumpy layer 112 is first formed over the protection layer 110 on the substrate 100. Then a reflection electrode 114 is formed on the bumpy layer 112. Since the bumpy layer 112 is made of organic material, from the micro point of view, its upper surface has many concave and convex areas, which form many bumps. This bumpy surface 111 of the bumpy layer 112, due to its concave and convex regions, can reflect the light which is incident to the reflection electrode 114 and scatter the light into multiple directions, providing a good reflection quality for the reflection electrode 114.

The conventional method of fabricating a thin film transistor array substrate for the liquid crystal display includes first making the source/drain electrode region and the data line, and followed by forming the reflective electrode. Therefore, two photo masks are needed to accomplish the processes for forming the source/drain electrode, the data line, and the reflective electrode, resulting in a higher fabrication cost.

### SUMMARY OF INVENTION

Therefore, the present invention provides a method of fabricating the thin film transistor array substrate for the liquid crystal display, in which the source/drain electrode, the data line and the reflective electrode are fabricated together using one photolithography step, improving from the prior art where two photo steps must be needed, so as to reduce the fabrication cost.

To realize at least the advantages mentioned above and avoid the drawbacks from the prior art process, the present invention provides a method of fabricating the thin film transistor array substrate of the reflective liquid crystal display. The method includes providing a substrate, forming a first conductive layer having a gate electrode and a scan line connected with the gate, forming a gate insulating layer covering over the substrate. A channel layer is formed over the gate. The method further includes forming a source/drain electrode region over the substrate, a data line connected with the source/drain electrode region and a second conductive layer serving as a reflective electrode. The characteristic is that the source/drain electrode region, the data line connected with the source/drain electrode region, and the reflective electrode are fabricated with one photolithography step. After that, a protection layer is formed over the substrate.

### BRIEF DESCRIPTION OF DRAWINGS

The invention can be more fully understood by reading the following detailed description of the preferred embodiments with reference made to the accompanying drawings.

FIGS. 1 to 5 are schematic diagrams showing the conventional process flow of fabricating thin film transistor array substrate of reflective liquid crystal display.

FIGS. 6 to 10 are schematic diagrams showing the process flow of fabricating thin film transistor array substrate of reflective liquid crystal display according to one preferred embodiment of the present invention.

FIGS. 11 to 12 are schematic diagrams showing a method of fabricating thin film transistor array substrate of reflective liquid crystal display according to another preferred embodiment of the current invention.

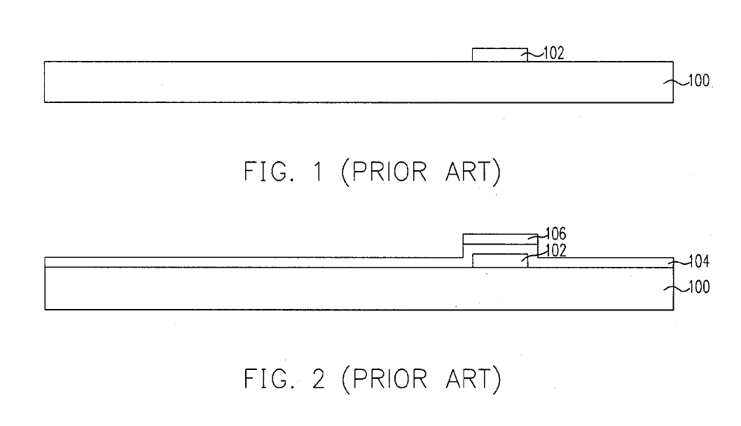

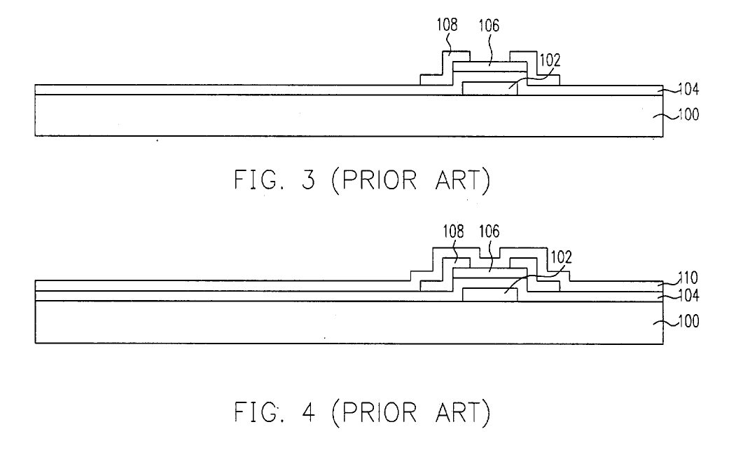

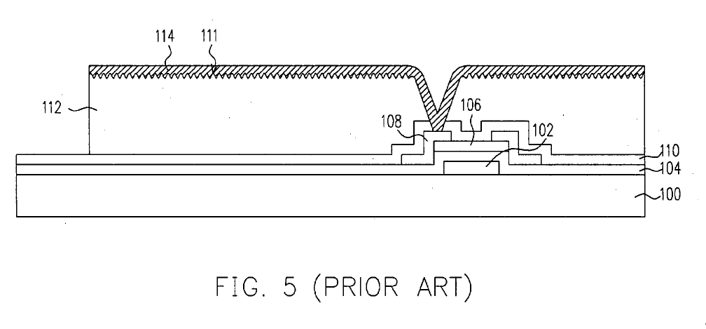

### DETAILED DESCRIPTION

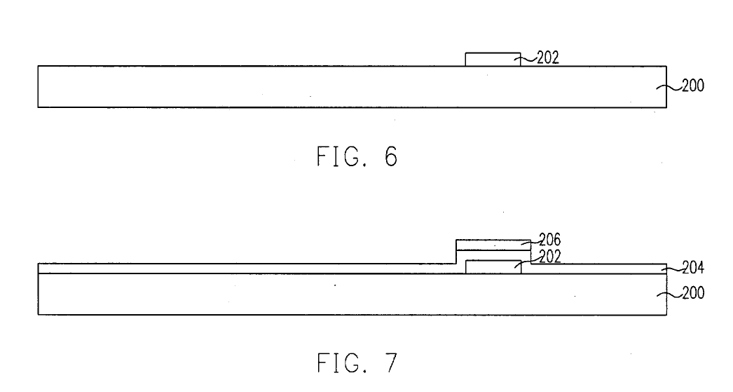

Referring to FIG. 6 to FIG. 10, they are schematic diagrams showing the process flow of fabricating thin film transistor array substrate of reflective liquid crystal display according to one preferred embodiment of the present invention. Referring first to FIG. 6, a substrate 200 is provided, where the substrate 200 can include, for example, a transparent glass substrate. A first conductive layer is formed over the substrate 200, wherein the first conductive layer includes a gate electrode 202 and a scan line (not shown) connected with the gate line 202. The first conductive layer can include the materials of, for example, nickel (Cr), tantalum (Ta), or other metal materials.

Next, referring to FIG. 7, after forming the first conductive layer, a gate insulating layer 204 is deposited over the substrate 200 and the gate electrode 202. The gate insulating layer 204 can include, for example, silicon nitride (SiNx) or silicon oxide (SiOx) having a proper dielectric constant ( ).

Referring to FIG. 7 again, after the formation of the gate insulating layer 204, a channel layer 206 is then formed over the gate insulating layer 204, which is above the gate electrode 202. The above mentioned channel layer 206 can be formed by, for example, depositing a blanket amorphous silicon layer, and followed by a photolithographic and etching processes to remove a portion of the amorphous silicon layer other than the gate electrode 202.

Further, referring to FIG. 8, a bumpy layer 212 is formed at the area where the reflective electrode is determined to locate, for example, at side region of the gate electrode 202 for the image pixel. This bumpy layer 212 can include, for example, an organic bump layer. Since the bumpy layer 212 includes, organic material, from the micro point of view, its upper surface has many concave and convex areas, forming many bumps, which thereby form a bumpy surface 211. As a result, the reflective electrode (not shown), which is formed later, can have very high reflecting quality.

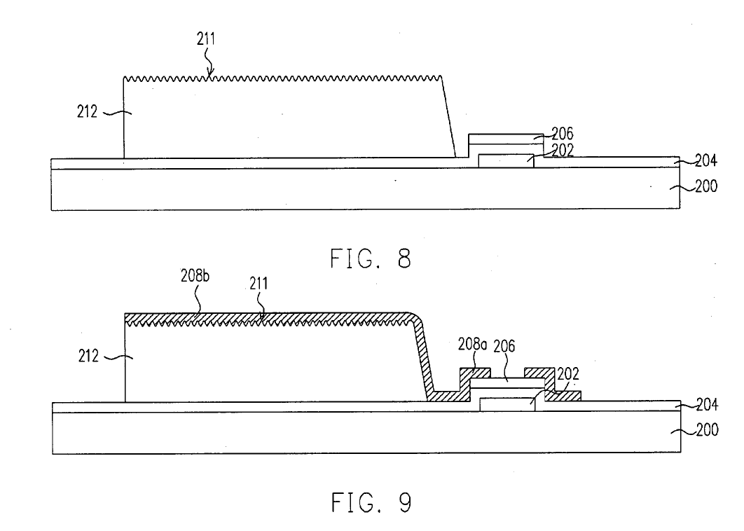

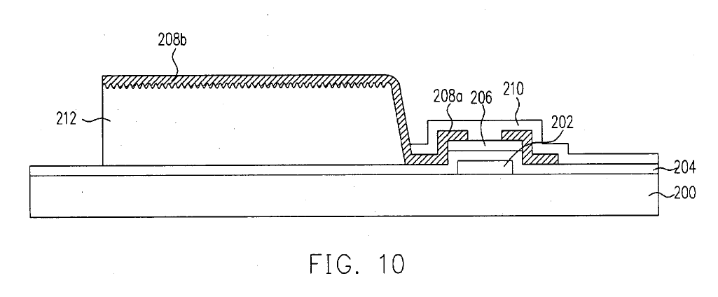

Next, referring to FIG. 9, a second conductive layer (not shown) is formed over the substrate 200, where this second conductive layer includes a source/drain electrode 208a, a data line (now shown) connected with the source/drain 208a, and a reflective electrode 208b. The second conductive layer can include metal materials such as, aluminum, nickel, or titanium, which can be used to form the source/drain electrode 208a and the reflective electrode 208b. Also as shown in FIG. 8, since the bumpy layer 212 provides a bumpy upper surface 211, which allows the reflective electrode 208b to reflect the incident light as well as scatter the incident light into different directions, resulting in a high reflecting quality of the reflective electrode 208b.

Referring to FIG. 10, a protection layer 210 is formed over the source/drain electrode 208a as well as the channel layer 206, in which the first part of fabricating the thin film transistor array substrate of the reflective liquid crystal display is accomplished.

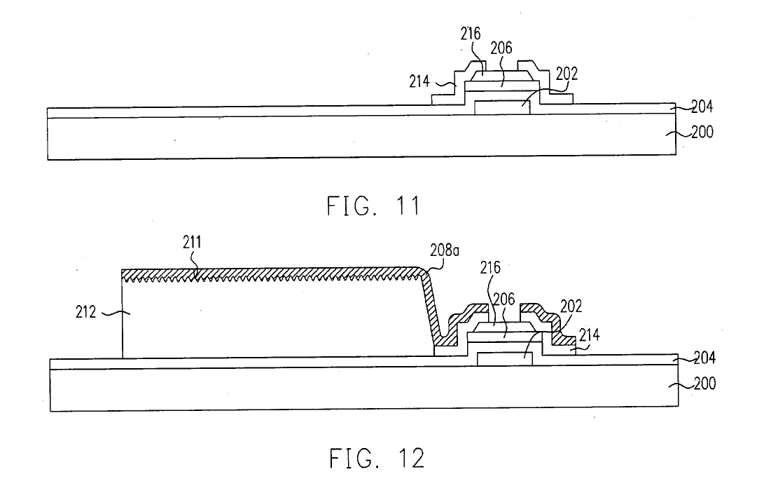

FIG. 11 and FIG. 12 are schematic diagrams showing another, according to another preferred embodiment of the invention, of fabricating thin film transistor array substrate of reflective liquid crystal display. For a typical thin film transistor structure, since the source/drain electrode 208a includes metal material such as aluminum, nickel or titanium, thus when the source/drain electrode 208a is directly in contact with the underneath channel layer 206 and the gate insulating layer 204, there are usually contact and electrical issues. Therefore, in the present invention, after the formation of the channel layer 206 and before the formation of the source/drain electrode 208a, a contact layer 214 including, for example, an n-type doped amorphous silicon material (n+a−Si) can be more advantageously formed in between the source/drain electrode layer 208a, and the channel layer 206 as well as the gate insulating layer 204.

Additionally, since the formation of the source/drain electrode 208a involves a step of etching process, it often cause the damage of the channel layer 206 due to improper control of the etching process. Therefore, the present invention can further form, for example, an etch stop layer 216 over the channel layer 206 between the contact layer 214, so as to prevent the channel layer 206 from being damaged.

FIG. 11 shows a schematic diagram of the process step of forming a contact layer 214 at both sides of the channel layer 206 after the channel layer 206 is formed and before the source/drain electrode 208a is formed. It also shows that an etch stop layer 216 is formed over the channel layer 206.

Further, FIG. 2 shows a diagram of the process step where, after forming the bumpy layer 212 and before forming the source/drain electrode 208a, a contact layer 214 is formed on both sides of the channel layer 206, and an etch stop layer 216 is further formed over the channel layer 206.

From the above detailed descriptions, the present invention includes at least the advantages.

1. In this invention, the method of fabricating the thin film transistor array substrate of reflective liquid crystal display includes forming the source/drain electrode, the data line and the reflective electrode together with one photolithography process, which greatly simplified the fabrication process.

2. In this invention, the method of fabricating the thin film transistor array substrate of reflective liquid crystal display further includes forming the source/drain electrode, the data line and the reflective electrode all together with only one photolithography process. It reduces one time for forming the photomask, comparing with the conventional method, thus further reduced the fabrication cost.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method of fabricating a thin film transistor array substrate of a reflective liquid crystal display, the method comprising:
providing a substrate, which including a first conductive layer, wherein the first conductive layer further includes a gate electrode;
forming a gate insulating layer covering over the substrate and the first conductive layer;
forming a channel layer over the gate electrode; and
forming a second conductive layer over the substrate, wherein the second conductive layer includes a source/drain electrode layer and a reflective electrode layer, which are formed at the same time.

2. The method of claim 1, further comprising a step of forming a contact layer prior to the step of forming the second conductive layer.

3. The method of claim 1, further comprising a step of forming an etch stop layer after the step of forming the channel layer.

4. The method of claim 1, further comprising a step of forming a protection layer covering over the second conductive layer after the step of forming the second conductive layer.

5. The method of claim 1, further comprising a step of forming a bumpy layer having an upper surface, wherein the reflective electrode is formed on the upper surface of the bumpy layer.

6. The method of claim 5, wherein the upper surface of the bumpy layer is a bumpy surface, which is used to increase a reflecting effect for the reflective electrode.

7. A method of fabricating a thin film transistor array substrate of a reflective liquid crystal display, comprising:
providing a substrate, wherein the substrate includes a first conductive layer, wherein the first conductive layer includes a gate electrode;
forming a gate insulating layer on the substrate, covering over the first conductive layer;
forming a channel layer over the gate electrode; and
forming a second conductive layer over the substrate, wherein the second conductive layer substantially includes a source/drain electrode layer and a reflective electrode layer, where the source/drain electrode layer and the reflective electrode layer are patterned at the same time.

8. The method of claim 7, further comprising a step of forming a contact layer prior to the step of forming the second conductive layer.

9. The method of claim 7, further comprising a step of forming an etch stop layer after the step of forming the channel layer.

10. The method of claim 7, further comprising a step of forming a protection layer covering the second conductive layer after the step of forming the second conductive layer.

11. The method of claim 7, further comprising a step of forming a bumpy layer having an upper surface, wherein the reflective electrode is formed on the upper surface of the bumpy layer.

12. The method of claim 11, wherein the upper surface of the bumpy layer is a bumpy surface, which is used to increase a reflecting effect for the reflective electrode.

13. A thin film transistor array substrate of a reflective liquid crystal display, comprising:
a substrate;
a first conductive layer disposed on the substrate, wherein the first conductive layer further comprises a gate electrode;
a gate insulating layer disposed over the substrate, covering over the first conductive layer;
a channel layer disposed over the gate electrode and the gate insulating layer; and
a second conductive layer, wherein the second conductive layer further comprises a source/drain electrode layer and a reflective electrode, wherein the reflective electrode is connected with one end of the source/drain electrode layer.

14. The substrate in claim 13, further comprising a contact layer, which is formed under the source/drain electrode layer of the second conductive layer.

15. The substrate of claim 13, further comprising an etch stop layer, which is formed over the channel layer.

16. The substrate of claim 13, further comprising a bumpy layer, and the reflective electrode of the second conductive layer is formed over the bumpy layer.

17. The substrate of claim 16, wherein the upper surface of the bumpy layer includes a bumpy surface.
